(19) United States
(12) Patent Application Publication
(10) Pub. No.: US 2023/0006419 A1
(43) Pub. Date: Jan. 5, 2023

(54) Tunable Light Source

(71) Applicant: Nippon Telegraph and Telephone Corporation, Tokyo (JP)

(72) Inventors: Yuta Ueda, Musashino-shi, Tokyo (JP); Takahiko Shindo, Musashino-shi, Tokyo (JP); Mitsuteru Ishikawa, Musashino-shi, Tokyo (JP)

(21) Appl. No.: 17/784,882

(22) PCT Filed: Dec. 16, 2019
(86) PCT No.: PCT/JP2019/049172

§ 371 Date: Jun. 13, 2022

(51) Int. Cl. H01S 5/068; H01S 5/06; H01S 5/343; H01S 5/125; H01S 5/22; H01S 5/34

(52) U.S. Cl. CPC H01S 5/068; H01S 5/0607; H01S 5/0601; H01S 5/34313; H01S 5/125; H01S 5/22; H01S 5/3403

(57) ABSTRACT

A tunable laser that is characterized by including a gain waveguide ACT made of an optically active semiconductor material, and a tunable wavelength filter TWF that selects light of a specific wavelength using current injection, which are integrated on a compound semiconductor substrate S, in which at least one or more of the tunable wavelength filters TWF are formed to select a specific wavelength of light from the light from the waveguide ACT and return the selected specific wavelength of light back to the waveguide ACT, and a semiconductor mixed crystal material constituting the tunable wavelength filter TWF has a strained multiple quantum well structure MQW in which a mixed crystal material ratio changes periodically.

### TECHNICAL FIELD

The present invention relates to a tunable light source, and more particularly to a tunable wavelength laser diode (TLD) in which an oscillation wavelength can be adjusted (tuned) in a wide wavelength range.

### BACKGROUND ART

Since a tunable laser is used in a wide range of applications such as carrier wave light sources for optical communication, gas sensing, and machining, its required characteristics also vary, but wideness of a wavelength range that can be covered by one light source is important. Here, the meaning of the wideness of a wavelength range in gas sensing using a tunable laser will be described.

In gas sensing using a tunable laser, utilizing the fact that a gas serving as a target has a light absorption spectrum specific to the gas, the presence or absence (a concentration), a temperature, and a pressure of the gas can be measured from a spectrum of reflected or transmitted light.

That is, by continuously performing wavelength sweeping of laser light emitted from a tunable laser, a state of a gas is detected from a light absorption intensity in the vicinity of a specific wavelength and a spectral width of an absorption curve.

By acquiring a plurality of absorption lines at once with one wavelength sweep, more information can be obtained from a target, and thus the wideness of a wavelength range that can be covered by a tunable laser directly leads to higher functionality of a sensing device thereof.

Although a method of mounting a plurality of tunable lasers having different wavelength bands on a sensing device is also conceivable, considering the costs of optical components for combining light rays emitted from different tunable lasers on the same optical path and the complexity of a control circuit for controlling a plurality of different tunable lasers, there is preferably only one laser that performs the wavelength sweep.

For example, in NPL 1 below, a distributed Bragg reflector (DBR) laser that has an oscillation wavelength of a 2 μm band using an InP-based semiconductor for CO₂ gas sensing is reported.

In a structure of the DBR laser in NPL 1, a bulk (generally indicating a layer thickness of several hundred nm or more) InGaAs (indium gallium arsenide) compound semiconductor material that is lattice-matched with InP (indium phosphide) is used in a DBR region and a phase adjustment (PH) region (collectively called a tuning region), and by injecting a current into the tuning region, a refractive index of the bulk InGaAs is changed to variably control the oscillation wavelength of the DBR laser.

Further, in the structure in NPL 1, a structure called a strained InGaAs/InGaAs multiple quantum well (strained MQW), in which a compound semiconductor having a multilayer structure constituting a multiple quantum well (MQW), for example, InGaAs material is distorted by periodically applying compression or elongation strain in an in-plane direction of layers in a thickness direction of the multilayer structure at a thickness equal to or less than a critical film thickness of the material, is used as an optically active semiconductor material (ACT) for laser oscillation.

A strained MQW is a method of realizing a structure that can be macroscopically regarded as a lattice matching system by periodically applying strain in opposite directions to each layer in a multilayer structure constituting an MQW at a film thickness equal to or less than a critical thickness, and in NPL 1, a tunable laser of a 2 μm band within which it is usually difficult to make InP-based semiconductors emit light (InP-based semiconductors generally have a longest light emission wavelength of about 1.65 μm) is realized.

### CITATION LIST

### Non Patent Literature

[NPL 1] Y. Ueda, et al., “2-μm band active distributed Bragg reflector laser for CO2 gas sensing”, Appl. Phys. Express, 12, 092011 (2019)

### SUMMARY OF THE INVENTION

### Technical Problem

The importance of the wideness of a wavelength range that can be covered by a tunable laser is as described above.

Here, in order to widen a wavelength range of a current injection type semiconductor tunable laser (in order to improve tuning efficiency), it is necessary to increase an amount of change in a refractive index due to carrier injection. It can be said that two main physical phenomena occur in a case in which a refractive index is changed by carrier injection into a semiconductor.

The first is a so-called carrier plasma effect in which a group of injected free carriers (plasma) is vibrated by an optical electric field, which conversely acts on an electric field, and as a result, a permittivity and a refractive index are changed, and a change in the refractive index is proportional to a free carrier density in a material.

The second is a phenomenon called a band filling effect, which is explained in relation to light absorption derived from a band gap of a semiconductor.

That is, it is an effect obtained by a light absorption spectrum being shifted to a higher energy side due to a conduction band being filled with electrons, or a valence band being filled with holes at an electron energy level in a semiconductor due to free carriers. This means that due to the Kramers-Kronig relationship, a refractive index spectrum of a material changes as an absorption spectrum changes.

In general, a larger band filling effect is obtained when the photon energy of light having an oscillation wavelength (about 0.62 eV in the case of a 2 μm band) is closer to the band gap energy of a semiconductor that causes a change in the refractive index due to current injection (in the case of InGaAs in a system lattice matching with InP described above, approximately 0.73 eV). That is, in a 2 μm DBR laser, the bandgap energy in a tuning region is preferably close to 0.62 eV within a range in which light absorption can be reduced to a low level.

However, in the sphere of Ga, As, and P-based mixed crystals, which are regarded as familiar materials from an engineering perspective, among compound semiconductors lattice-matched to InP, those having a smaller bandgap energy than InGaAs are not known.

This means that it is difficult to improve the tuning efficiency in the range of materials that are lattice-matched to InP.

The present invention is proposed to solve these problems. That is, it is an object of the present invention to provide a tunable laser having a higher tuning efficiency than a conventional one in a semiconductor laser having a long wavelength in consideration of a normal compound semiconductor, for example, an InP semiconductor, such as a 2 μm band TLD (a tunable laser).

### Means for Solving the Problem

As described above, an optically active material having a long light emission wavelength (small bandgap energy) is obtained due to a strained MQW structure. In order to overcome the above problems, the present invention uses a material having a reduced bandgap energy in a tuning region of a tunable laser.

An example of an embodiment of the present invention is characterized by having the following configurations in order to achieve such an object.

### Configuration 1

A tunable laser including a compound semiconductor substrate, a gain waveguide composed of an optically active semiconductor material integrated on the compound semiconductor substrate, and a tunable wavelength filter for selecting light of a specific wavelength using current injection integrated on the compound semiconductor substrate, in which at least one or more of the tunable wavelength filters are formed to select a specific wavelength of light from the light from the gain waveguide and return the selected specific wavelength of light back to the gain waveguide, and a semiconductor mixed crystal material constituting the tunable wavelength filter has a strained multiple quantum well structure in which a mixed crystal material ratio changes periodically.

### Configuration 2

In the tunable laser according to Configuration 1, a peak wavelength of photoluminescence light emission of the semiconductor material constituting the gain waveguide is longer than 1.65 μm.

### Configuration 3

In the tunable laser according to Configuration 2, a semiconductor material constituting the gain waveguide has a strained multiple quantum well structure.

### Configuration 4

In the tunable laser according to any one of Configurations 1 to 3, the peak wavelength of photoluminescence light emission of the strained multiple quantum well structure constituting the tunable wavelength filter is separated from the shortest wavelength among oscillation wavelengths of the tunable laser by 50 nm or more toward a shorter wavelength side.

### Configuration 5

In the tunable laser according to any one of Configurations 1 to 4, further including one or more phase adjusters for adjusting a resonator length of an optical resonator constituting the tunable laser are provided, wherein a material constituting the phase adjuster has the same strained multiple quantum well structure as the tunable wavelength filter.

### Configuration 6

In the tunable laser according to any one of Configurations 1 to 5, further including electro-absorption type light intensity modulators monolithically integrated on the compound semiconductor substrate for modulating an intensity of output laser light.

### Configuration 7

In the tunable laser according to any one of Configurations 1 to 6, wherein the compound semiconductor substrate is an InP substrate, and the strained multiple quantum well structure is a strained InGaAs/InGaAs multiple quantum well.

### Effects of the Invention

According to the semiconductor optical element structure of the tunable laser of the present invention described above, it is possible to widen a tunable wavelength range covered by a tunable light source, and it is possible to further widen an application range of the tunable laser.

### BRIEF DESCRIPTION OF DRAWINGS

FIG. 1 is a plan view of a substrate of a 2 μm band DBR type tunable laser according to Example 1.

FIG. 2 is a cross-sectional view (a) of a substrate of a gain waveguide (ACT) IIa of the DBR laser of FIG. 1 and a cross-sectional view (b) of a substrate of a ridge waveguide IIb of a tuning region (DBR, PH).

FIG. 3 shows calculation results of two PL spectra of a strained InGaAs/InGaAs multiple quantum well of Example 1 and a bulk InGaAs for comparison.

FIG. 4 is a graph comparatively showing a relationship between an injection current density and a reflected peak wavelength shift amount in a case in which bulk InGaAs and strained InGaAs/InGaAs multiple quantum wells are used in a DBR region.

FIG. 5 is a plan view of a substrate of a modulator-integrated tunable laser in which electro-absorption type optical modulators (EAMs) using the same material as the tuning region of Example 2 are integrated.

FIG. 6 is a diagram showing a reverse voltage V and a light absorption change (attenuation rate) of the EAM of Example 2.

### DESCRIPTION OF EMBODIMENTS

Hereinafter, embodiments of the present invention will be described in detail with reference to the figures.

### EXAMPLE 1

As Example 1 of the present invention, an example of realizing expansion of an oscillation wavelength range of a 2 μm band DBR type semiconductor tunable laser for CO₂ gas sensing will be shown.

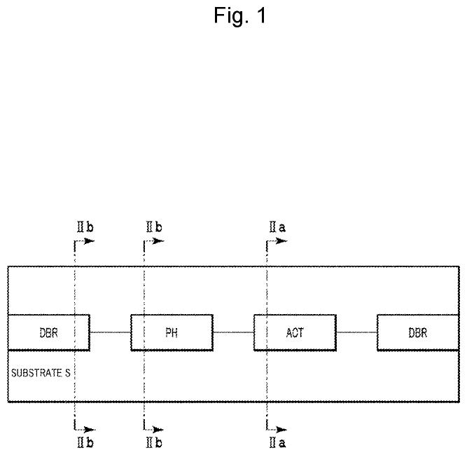

FIG. 1 is a plan view of a substrate of a tunable laser of Example 1. In FIG. 1, an optically active gain waveguide ACT, two distributed Bragg reflectors (DBRs) on left and right ends that reflect a specific wavelength to ACT, and a phase adjuster PH that finely adjusts a resonator length serving as a resonator are disposed on the same optical axis on an n-type doped substrate S.

For example, InP is selected as a compound semiconductor substrate S in FIG. 1, and as the gain waveguide ACT made of an optically active semiconductor material, for example, a strained InGaAs/InGaAs multiple quantum well structure (a strained multiple quantum well structure, or a strained MQW structure), in which an amount of strain is periodically changed by periodically changing a material component ratio of a semiconductor mixed crystal material of each layer constituting the MQW, is used. In the strained MQW structure, a peak wavelength (PL wavelength) of photoluminescence (PL) light emission can be adjusted by adjusting the amount of strain.

In Example 1, a tunable laser having a longer oscillation wavelength than a normal InP substrate-based semiconductor laser is realized by using the strained MQW structure for the gain waveguide ACT. In the gain waveguide ACT of Example 1 of FIG. 1, the amount of strain of the strained MQW structure is set such that the peak wavelength (PL wavelength) in a wavelength spectrum of the photoluminescence (PL) light emission of the gain waveguide ACT is 2.015 μm (>1.65 μm).

In Example 1 of FIG. 1, the tunable laser is realized by using a DBR that can change a reflected peak wavelength using current injection as a tunable wavelength filter TWF that determines an oscillation wavelength of a laser. A pitch of a diffraction grating of the DBR is determined such that the reflected peak wavelength of the DBR is 2.025 μm in the absence of current injection.

Here, a case in which the oscillation wavelength of the DBR laser is shifted to a short wavelength side by a maximum of about 10 nm using current injection into the DBR portion is considered. Accordingly, the shortest wavelength lm of the oscillation wavelength of the laser of Example 1 is 2.015 μm.

As the tunable wavelength filter TWF, in addition to a DBR, a ring resonator, a sampling diffraction grating Bragg reflector, or the like can be considered, but as long as it is a tunable wavelength filter TWF that returns light of a specific wavelength to the waveguide ACT due to wavelength selectivity, the configuration is not limited.

Further, in FIG. 1, an optical resonator is formed by sandwiching the waveguide ACT between the two DBRs, but in the case of a reflector having one reflection wavelength peak such as a DBR, one side of the waveguide ACT may be a DBR and the other side may be a reflector having no wavelength dependence such as a cleaved surface mirror.

That is, at least one or more of the tunable wavelength filters TWF may be formed to select a specific wavelength of light from the light from the gain waveguide ACT and return the selected specific wavelength of light back to the gain waveguide ACT.

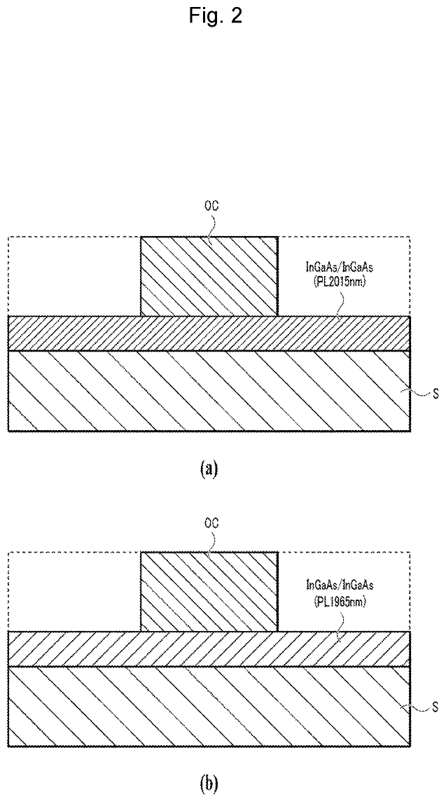

FIGS. 2(a) and 2(b) are cross-sectional views of the substrate perpendicular to the optical axis in a cross-sectional portion of ACT (IIa) and DBR or PH (IIb) of FIG. 1.

In the cross-sectional view of the gain waveguide ACT of FIG. 2(a), for example, the strained MQW (strained InGaAs/InGaAs quantum well structure) in which the PL peak is set to 2.015 μm is grown in multilayers on the n-type doped substrate S of a compound semiconductor such as InP such that a total layer thickness is 300 nm. An over-cladding layer OC made of p-type InP is laminated thereon.

Similarly, in the cross-sectional view of the DBR portion and the PH portion of FIG. 2(b), the strained MQW (strained InGaAs/InGaAs quantum well structure) in which the PL peak is set to 1.965 μm is grown in multilayers on the n-type doped substrate S such that the total layer thickness is 300 nm, and the over-cladding layer OC made of p-type InP is laminated thereon.

In each portion, the over-cladding portion OC forms a ridge-type optical waveguide by other portions being removed while leaving an over-cladding layer with a width of about 2 μm along an optical path.

In Example 1, as shown in FIG. 2(b), the peak wavelength of the photoluminescence light emission (a PL value in parentheses in FIG. 2) made of a semiconductor material forming a tuning region (the DBR portion or the phase adjuster PH) is configured of the strained MQW structure such that the shortest oscillation wavelength of the tunable DBR laser is 1.965 μm, which is 50 nm shorter than the shortest oscillation wavelength lm=2.015 μm.

In the present specification, a difference between the oscillation wavelength of the laser and the PL peak wavelength of the strained InGaAs/InGaAs multiple quantum well in the tuning region is called detuning. In the present invention, a tunable range of the oscillation wavelength of the laser can be increased by adopting the strained MQW structure in the tuning region and setting an amount of detuning to be small in this way. In a conventional structure described in NPL 1, since a bulk InGaAs material that is lattice-matched with InP was used for the tuning region, the amount of detuning could not be set in this way.

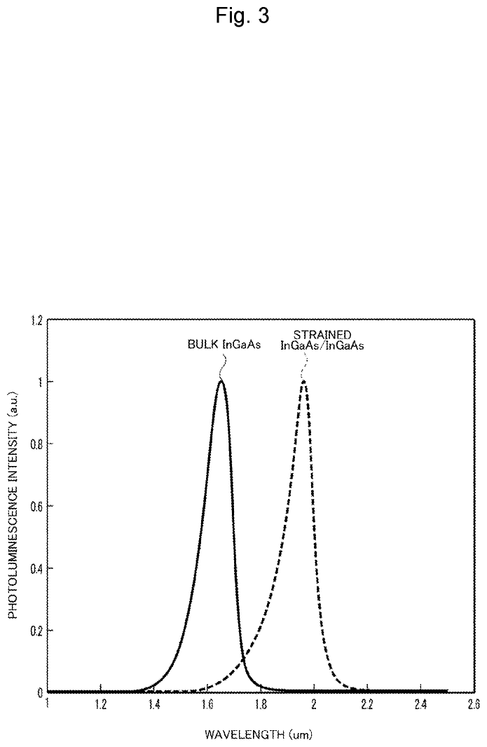

FIG. 3 shows calculation results of two PL spectra of the strained InGaAs/InGaAs quantum well (the dotted line on the right side) of the DBR or PH portion of Example 1 and the bulk InGaAs (the solid line on the left side) of a lattice matching system for comparison.

In the strained InGaAs/InGaAs quantum well structure of Example 1, well layers and barrier layers configured in different mixed crystal material ratios are periodically and alternately laminated, and, for example, a thickness/an amount of strain of the well layer and the barrier layer may be set to, for the well layer, 10 nm/a compression of 1.5%, and for the barrier layer, 10 nm/an elongation of 1%. By adjusting the mixed crystal material ratio for each layer, the amount of strain of each layer can be adjusted, and the PL peak wavelength of the strained MQW can be adjusted.

The reason for detuning the PL peak wavelength in the tuning region (the DBR and the PH) to 1.965 μm which is a shorter wavelength by 50 nm or more with respect to the shortest oscillation wavelength lm of the target tunable laser is to avoid a problem in which, in using a band filling effect, when the PL wavelength in the tuning region is too close to the oscillation wavelength of the semiconductor laser, a light loss due to light absorption becomes significant.

Further, in the first embodiment of FIG. 1, in addition to the ACT and the DBR, the phase adjuster PH for adjusting an effective optical path length of a resonator is also provided. This is because an optical path length of a resonator can be adjusted by changing an amount of excitation current in an optically active region input to the ACT, but in that case, since the light output is also changed, one with the phase adjuster PH has better controllability as a tunable light source.

In addition, the semiconductor material of the phase adjuster PH is also a strained InGaAs/InGaAs multiple quantum well with a photoluminescence peak wavelength of 1.965 μm, which is the same as the semiconductor material of the DBR region described above.

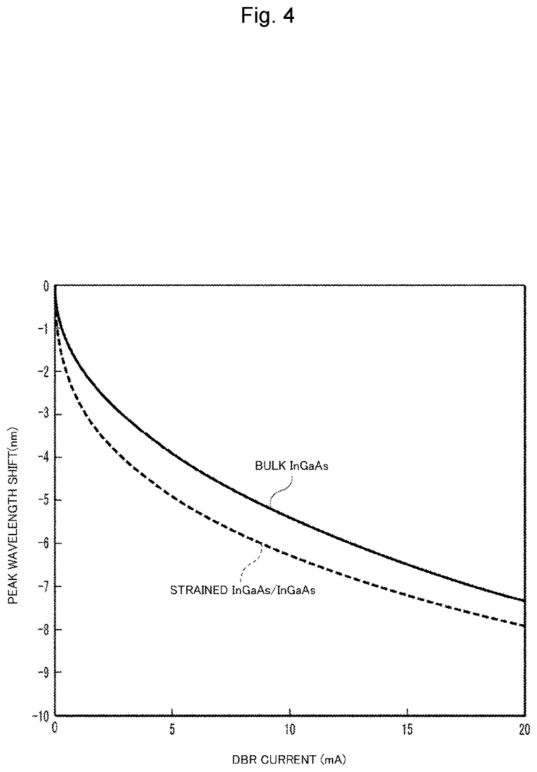

FIG. 4 shows two graphs comparatively showing a relationship between an amount of current to the DBR region and an amount of shifting of a DBR reflection peak in two cases of a strained InGaAs/InGaAs multiple quantum well (a dotted line) with a photoluminescence peak wavelength of 1.965 μm and a strain-free InGaAs (bulk InGaAs, a solid line).

The same calculation model as in NPL 1 is used for a method for calculating an amount of change in a refractive index with respect to an amount of current injection required for an amount of wavelength shift. When the amount of wavelength shift is estimated from a change in carrier density, a confinement coefficient of a light mode is required, but here, 0.5 was set for bulk InGaAs, and the strained InGaAs/InGaAs MQW was set to 0.25, which is half of that.

As shown in FIG. 4, it can be seen that the amount of wavelength shift in the DBR region due to the strained InGaAs/InGaAs MQW is improved (an absolute value thereof is increased) compared with that of the bulk. Here, the calculation was made using the amount of wavelength shift in the DBR region (proportional to the amount of change in the refractive index) as an example, but since an amount of phase adjustment of a phase adjustment region PH is also proportional to the amount of change in the refractive index, an effect of improving the amount of phase adjustment is the same as that of the example of FIG. 4.

### EXAMPLE 2

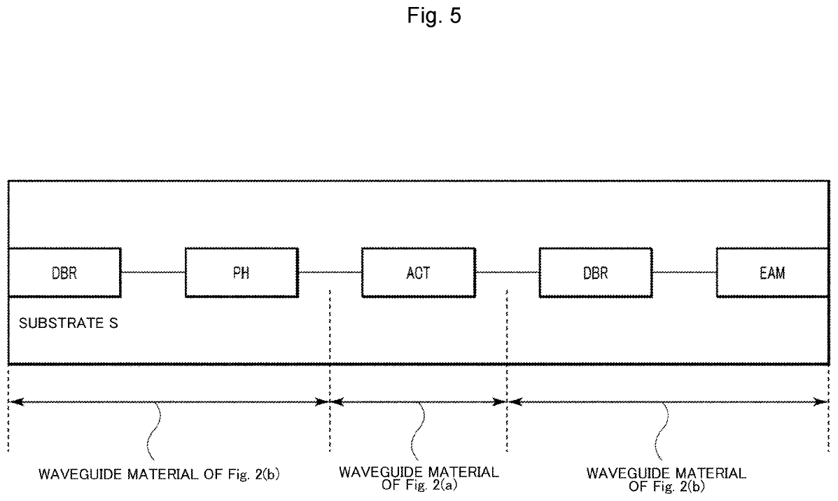

FIG. 5 shows, as Example 2 of the present invention, a configuration in which an electro-absorption type light intensity modulator EAM that modulates an intensity of output laser light is integrated in the tunable laser of Example 1.

In Example 1, the amount of detuning of the InGaAs/InGaAs strained quantum well in the tuning region was set to 50 nm in order to achieve the band filling effect. However, in this degree of the amount of detuning, when a modulation signal is applied to the structure of Example 1 together with a bias electric field in an opposite direction (the potential of the over-cladding layer OC of the p-type InP is negative with respect to the n-type InP substrate S), an electro-absorption type light intensity modulation function due to the exciton absorption shift can be obtained.

Accordingly, in Example 2, a modulation electrode that applies a reverse bias together with the modulation signal is added in the structure of the waveguide material that is exactly the same as the tuning region shown in FIG. 2(b) of Example 1, and thus the light intensity modulator EAM of Example 2 can be easily integrated.

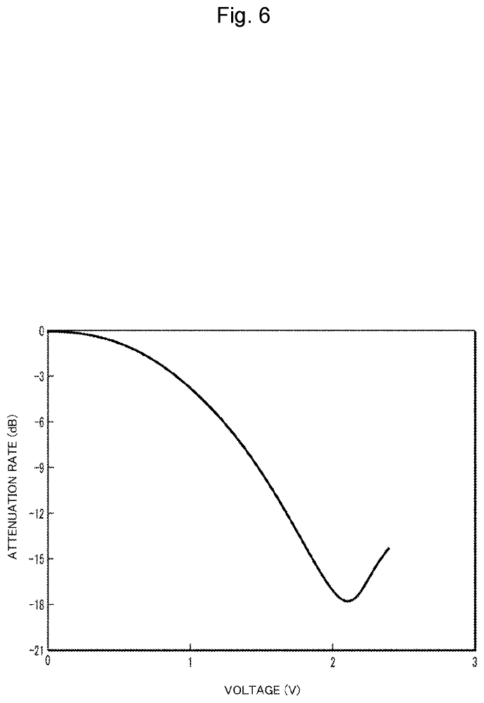

FIG. 6 shows a change in a light attenuation rate (dB) with respect to the light of 2.015 μm in the EAM of Example 2 in which the light intensity modulation function is realized by applying a reverse voltage V to the waveguide structure of FIG. 2(b), that is, the same structure as the waveguide structure of the tuning region of the tunable laser of Example 1. A length of the waveguide structure (EAM) to which the reverse electric field is applied is 100 μm. Since a size of the DBR type tunable light source is generally less than 1000 μm, it can be said that this EAM is sufficiently small in size when considering integration in the tunable light source. From FIG. 6, with the EAM of this size, a light attenuation of about 15 dB is obtained with a bias of about −2 V, and sufficient quenching characteristics are obtained for practical use.

For example, in sensing applications of the tunable light source, a method for changing not only a wavelength of light but also an intensity of light over time is adopted. The light whose intensity is modulated at a frequency f0 in time is sent to a sensing target, and the light intensity of the received light is synchronously detected at the frequency f0, and thus high S/N sensing can be performed.

In order to modulate the light intensity, a method for changing a light output from a resonator by changing an amount of current to the ACT portion of the tunable light source (direct modulation) can be considered. However, as described in Example 1, when the amount of current to the ACT portion is changed, the resonator length as a resonator will change, and this causes fluctuations in the oscillation wavelength in the tunable light source, and thus it is not suitable for sensing that uses the oscillation wavelength.

Further, it is also possible to modulate the light output by integrating an optical semiconductor amplifier SOA that amplifies the light output with the output of the semiconductor laser and changing the amount of current to the SOA.

However, since this method dynamically modulates the amount of current to the SOA, heat generated from the SOA portion also fluctuates periodically. In a case in which a thermal crosstalk from the SOA to the tunable laser is equal to or more than a certain level, the oscillation wavelength of the tunable laser also fluctuates.

Generally, integrating an electro-absorption type light modulator that generates less heat than an SOA at the output of the tunable light source, is advantageous for realizing a light intensity modulation function while ensuring wavelength controllability.

### INDUSTRIAL APPLICABILITY

As described above, in the tunable laser of the present invention, it is possible to improve the tuning efficiency and widen the tunable wavelength range covered with the tunable light source, and further widen the application range of the tunable laser.

1. A tunable light source comprising:
a compound semiconductor substrate;
a gain waveguide composed of an optically active semiconductor material integrated on the compound semiconductor substrate; and,
a tunable wavelength filter for selecting light of a specific wavelength using current injection integrated on the compound semiconductor substrate,
wherein:
at least one or more of the tunable wavelength filters are formed to select a specific wavelength of light from the light from the gain waveguide and return the selected specific wavelength of light back to the gain waveguide; and,
a semiconductor mixed crystal material constituting the tunable wavelength filter has a strained multiple quantum well structure in which a mixed crystal material ratio changes periodically.

2. The tunable light source according to claim 1, wherein
a peak wavelength of photoluminescence light emission of the semiconductor material constituting the gain waveguide is longer than 1.65 μm.

3. The tunable light source according to claim 2, wherein
a semiconductor material constituting the gain waveguide has a strained multiple quantum well structure.

4. The tunable light source according to claim 1, wherein
the peak wavelength of photoluminescence light emission of the strained multiple quantum well structure constituting the tunable wavelength filter is separated from the shortest wavelength lm among oscillation wavelengths of the tunable laser by 50 nm or more toward a shorter wavelength side.

5. The tunable light source according to claim 1, further comprising:
one or more phase adjusters for adjusting a resonator length of an optical resonator constituting the tunable laser are provided, wherein
a material constituting the phase adjuster has the same strained multiple quantum well structure as the tunable wavelength filter.

6. The tunable light source according to claim 1, further comprising:
electro-absorption type light intensity modulators monolithically integrated on the compound semiconductor substrate for modulating an intensity of output laser light.

7. The tunable light source according to claim 1, wherein:
the compound semiconductor substrate is an InP substrate; and,
the strained multiple quantum well structure is a strained InGaAs/InGaAs multiple quantum well.
